(19) United States
(12) Patent Application Publication
(10) Pub. No.: US 2020/0041556 A1
(43) Pub. Date: Feb. 6, 2020

(54) APPARATUS FOR TESTING TRAILER FUNCTIONS

(71) Applicant: Jason Hamila, Cleveland, OH (US)

(72) Inventor: Jason Hamila, Cleveland, OH (US)

(21) Appl. No.: 16/530,556

(22) Filed: Aug. 2, 2019

Related U.S. Application Data
(60) Provisional application No. 62/713,755, filed on Aug. 2, 2018.

(51) Int. Cl. G01R 31/00; G07C 5/08; B62D 53/06

(52) U.S. Cl. CPC G01R 31/007; B62D 53/06; G07C 5/0858

(57) ABSTRACT

The present disclosure relates to a portable device for testing the lighting elements of a trailer. The testing device includes a universal connector configured to receive interchangeable connector portions wherein each connector portion is adapted to fit a specific trailer lighting receptacle.

This application claims priority benefit of U.S. Provisional Patent Application Ser. No. 62/713,755 filed Aug. 2, 2018, entitled “APPARATUS FOR TESTING TRAILER FUNCTIONS,” the complete disclosure of which, in its entirety is herein incorporated by reference.

### BACKGROUND

The present exemplary embodiments relate to methods and devices for testing various functions of a vehicle trailer. It finds particular application in conjunction with testing the lighting operations of a semi-truck trailer and will be described with particular reference thereto. However, it is to be appreciated that the present exemplary embodiments are also amenable to other like applications.

Presently, drivers of semi-trucks are required by law to inspect the truck (cab) and trailer before embarking on a trip. The pre-trip inspection includes a verification that all lighting elements of the truck and trailer are operational. One method to inspect the lights includes mating the truck to the trailer and activating each lighting element using the controls in the cab of the truck. For example, the right turn signal may be activated from within the cab and the driver exits the cab and walks around the truck and trailer to ensure that the right turn signal is working. Once the lighting element is verified as working, the driver re-enters the cab of the truck and actuates another lighting element, such as the clearance lights of a trailer, followed by another walking trip around the truck and trailer to ensure that particular lighting element is operational. This method is disadvantageous as it requires a single person to take multiple trips walking around the truck and return to the cab for activating each light and requires the truck cab to be hooked to the trailer as a power source.

Another method to inspect the lights of a trailer during a pre-trip inspection is to wheel (cart) or carry a large testing device in close proximity to the trailer and connect a long cable of the large device to the trailer. The large device generally includes a lead-acid battery coupled to a heavy main unit that must be set on the ground or wheeled on a cart. The long cable is then attached from the main unit to a receptacle on the trailer. The main unit includes a user interface allowing a user to select a desired lighting function. While the cart unit has advantages over mating a truck to the trailer, these cart units are bulky and heavy devices that are cumbersome to wheel around a trailer yard and bring on a trip and require a person to return to the location of the unit to actuate different lighting elements.

The following discloses certain improvements that overcomes one or more drawbacks associated with prior art arrangements.

### BRIEF DESCRIPTION

Various details of the present disclosure are hereinafter summarized to provide a basic understanding. This summary is not an extensive overview of the disclosure and is neither intended to identify certain elements of the disclosure nor to delineate scope thereof. Rather, the primary purpose of this summary is to present concepts of the disclosure in a simplified form prior to the more detailed description that is presented hereinafter.

In accordance with one exemplary embodiment of the present disclosure, a device for testing the functions of a trailer is provided. The testing device includes a main unit comprising a housing. A power supply is located within the housing along with a wireless communication interface. The wireless communication interface is configured to wirelessly communicate with a remote comprising a user interface. The testing device also includes a connection interface configured to connect the main unit to a connector portion, the connector portion comprising a first end configured to engage the connection interface and a second end configured to engage a trailer receptacle.

In accordance with another exemplary embodiment, a tester device for testing the functions of a trailer includes a main unit having a housing holding a power supply. The tester device also includes a connection interface with a plurality of first connection elements. The connection interface is configured to removably connect the main unit to a connector portion. The connector portion includes a plurality of second connection elements. The connector portion includes a first end configured to mechanically engage the connection interface wherein one of each of the first connection elements is electrically connected to one of each of the second connection elements. The connector portion also includes a second end that is configured to engage a trailer receptacle, wherein the connector portion electrically connects each of the first connection elements of the connection interface to the trailer receptacle.

In some embodiments, the tester device includes a wireless communication interface located within the housing and in communication with the power supply; wherein the wireless communication interface is configured to wirelessly communicate with a remote comprising a user interface.

In some embodiments, the connection interface is a 7-pin connector having 7 connection elements.

In some embodiments, the remote is a smart device, such as a smartphone, or tablet.

In some embodiments, the power supply is a battery, including a rechargeable battery. The battery has a lithium ion or lithium polymer-based chemistry. In some embodiments, the battery has a capacity of less than 3000 mAh.

In some embodiments, the main unit of the tester device unit weighs from about 1.5 lbs. to about 2 lbs.

In some embodiments, the housing has a, length from about 5 inches to about 8 inches, a width from about 3.5 inches to about 5.5 inches and a height from about 1.25 inches to about 3 inches.

In some embodiments, the tester device is configured to mechanically engage with the trailer and project outwardly from a surface of the trailer. In some embodiments, the tester device projects outwardly at an angle, the angle defined between the surface of the trailer and device, wherein the angle is from about 30 degrees to about 60 degrees.

In some embodiments, the tester device further includes a lighting element.

In some embodiments, the connection interface is configured to removably engage interchangeable connector portions.

In some embodiments, the connection interface and connector portion include a corresponding threaded attachment cap for securing the connector potion to the connector interface.

In accordance with another exemplary embodiment of the present disclosure, a tester device for testing the functions of a trailer includes a power supply and a connection interface including a plurality of connection elements. The tester device also includes a plurality of relays in electronic communication with the power supply and the connection interface, wherein each relay of the plurality of relays is associated with one connection element of the plurality of connection elements. The tester device also includes a processor in electronic communication with the plurality of relays. The processor is configured to actuate at least one relay, wherein actuation of the at least one relay allows the transfer of electric power from the power supply to the associated connection element wherein the associated connection element is configured to supply power to a trailer connection element in order to operate a function of the trailer.

In some embodiments, the tester device further includes a wireless communication interface in electronic communication with the processor; wherein the wireless communication interface is configured to wirelessly communicate commands to the processor for actuating at least one relay of the plurality of relays from an associated remote comprising a user interface.

In some embodiments, the connection interface is configured to removably connect to a connector portion, wherein the connector portion includes a first end configured to mechanically engage the connection interface and a second end configured to engage a trailer receptacle.

A primary advantage is associated with the testing trailer functions, and particularly, when testing is conducted by a single person

Another benefit relates to the compact, lightweight component(s) of the testing apparatus.

Yet another advantage resides in the wireless communication interference that enhances remote connection between various components of the testing apparatus.

Still other benefits and advantages will become apparent upon reading and understanding the following detailed description and reviewing the accompanying drawings.

These and other non-limiting characteristics of the disclosure are more particularly disclosed below.

### BRIEF DESCRIPTION OF THE DRAWINGS

The following is a brief description of the drawings, which are presented for the purposes of illustrating the exemplary embodiments disclosed herein and not for the purposes of limiting the same.

FIG. 1 illustrates a front left side perspective of a semi-truck trailer.

FIG. 2 illustrates a rear right side perspective of a semi-truck trailer.

FIG. 3 illustrates a trailer plug in accordance with the present disclosure.

FIG. 4 illustrates a perspective view of a light testing device in accordance with the present disclosure.

FIG. 5 illustrates a rear view of the light testing device in accordance with the present disclosure.

FIG. 6 illustrates a front view of a light testing device in accordance with the present disclosure.

FIG. 7 illustrates a light testing device connected to a trailer in accordance with the present disclosure.

FIG. 8 is a block diagram of the components of a trailer light tester in accordance with the present disclosure.

FIG. 9 illustrates a front left side perspective of a semi-truck trailer with a light testing device and remote in accordance with the present disclosure.

FIG. 10 illustrates a light testing device in accordance with the present disclosure.

FIG. 11 illustrates a connector portion and trailer receptacle in accordance with the present disclosure.

### DETAILED DESCRIPTION

A more complete understanding of the components, processes and apparatuses disclosed herein can be obtained by reference to the accompanying drawings. These figures are merely schematic representations based on convenience and the ease of demonstrating the present disclosure, and are, therefore, not intended to indicate relative size and dimensions of the devices or components thereof and/or to define or limit the scope of the exemplary embodiments.

Although specific terms are used in the following description for the sake of clarity, these terms are intended to refer only to the particular structure of the embodiments selected for illustration in the drawings and are not intended to define or limit the scope of the disclosure. In the drawings and the following description below, it is to be understood that like numeric designations refer to components of like function.

The singular forms “a,” “an,” and “the” include plural referents unless the context clearly dictates otherwise.

As used in the specification and in the claims, the term “comprising” may include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named ingredients/components/steps and permit the presence of other ingredients/components/steps. However, such description should be construed as also describing compositions, articles, or processes as “consisting of” and “consisting essentially of” the enumerated ingredients/components/steps, which allows the presence of only the named ingredients/components/steps, along with any impurities that might result therefrom, and excludes other ingredients/components/steps.

Numerical values in the specification and claims of this application should be understood to include numerical values which are the same when reduced to the same number of significant figures and numerical values which differ from the stated value by less than the experimental error of conventional measurement technique of the type described in the present application to determine the value.

One or more embodiments will now be described with reference to the attached drawings, wherein like reference numerals are used to refer to like elements throughout.

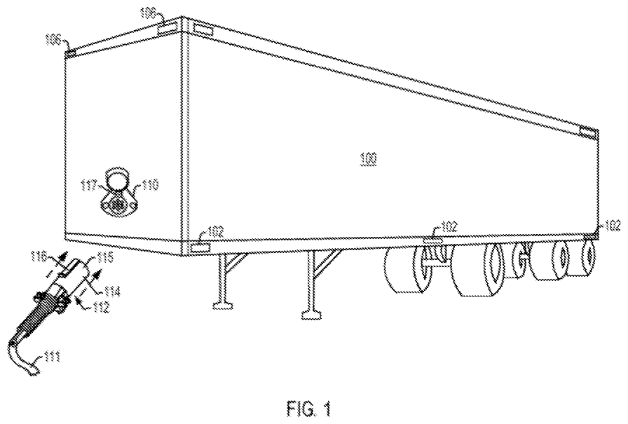

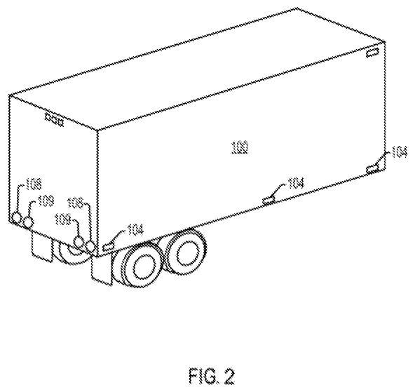

Referring now to FIGS. 1 and 2, there is shown an illustration of a semi-truck trailer 100. The semi-truck trailer 100 is configured to connect to and be transported by a truck (not pictured). Generally, the semi-truck trailer 100 is from about 25 feet to about 55 feet long, about 8.5 feet wide, and about 13.5 feet high (including the wheels) although the dimensions should not be construed as limiting the invention. The semi-truck trailer 100 includes a plurality of lighting elements (e.g., 102, 106) positioned in various locations about the trailer 100. Traffic laws require that certain lighting elements be in certain locations and that the lighting elements are functional while the vehicle and trailer 100 are traveling on the road. FIG. 1 is a front left side (driver's side) perspective view of a trailer 100 with certain lighting elements visible. As illustrated, the trailer 100 includes left side marker lights 102 and clearance lights 106. The marker lights 102 are activated by a driver to indicate that the truck will be initiating a left turn or merging into the left lanes in the highway. That is, when the truck driver anticipates making a left turn, the driver(s) in the cab of the truck activates a control that sends an electrical signal to the left marker lights 102 such that the left marker lights 102 repeatedly turn on and off (“blink”). The clearance lights 106 provide visibility to the trailer 100 during poor environmental lighting conditions and help the driver to determine whether the top of the truck and trailer 100 is going to clear the bottom of a low overpass by the reflection of lights on the overpass. Regulations proscribe that trailers over 80 inches wide have these lights 106 for identification purposes. That is, the clearance lights 106 alert other driver's to the wider truck's presence on the road. The clearance lights 106 are usually activated by a control in the cab of an associated truck and are constantly on, i.e., they do not “blink” in a repeating pattern like the marker lights 102.

As illustrated in FIG. 2, the trailer 100 also includes, for example, right marker lights 104, rear tail lights 108 and stop lights 109. Although illustrated at separate locations on the trailer 100 in FIG. 2, in some embodiments, the rear tail lights 108 and stop lights 109 are configured within the same lighting element housing wherein the housing may include a light element (e.g., a light bulb) for tail lights and a light element for the stop light. In some embodiments, a single bulb is capable of illumination at different intensities for each function, e.g., the rear tail lights illuminate at a desired intensity and during braking, the stop light illuminates at a greater intensity. Generally, the rear tail lights 108 indicate a vehicle's presence and width on the road, while the stop lights 109 indicate that the vehicle is braking (slowing down).

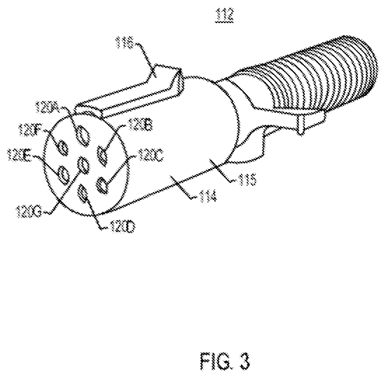

With continued reference to FIG. 1, the trailer 100 includes a first connection, preferably, a receptacle 110. The receptacle 110 is generally configured to receive a cable 111 having a second connection, preferably a cable plug 112. The cable plug 112 and receptacle 110 have corresponding pin and sleeve connectors (connection elements) such that electrical (and mechanical) connection between each are made when the cable plug 112 is engaged into the lighting receptacle 110. The exemplary cable plug 112 shown in FIG. 3 is presented with a total of seven (7) connection elements 120A-G, (pins or sleeves) embedded within a cylindrical plug body 114. Generally, in association with standard truck trailers, such as trailer 100, connector 120A is a ground, 120B corresponds to the rear tail lights 108, 120C corresponds to the right markers 104, 120D corresponds to the stop lights 109, 120E corresponds to the left markers 102, 120F corresponds to the overhead clearance lights 106 and 120G corresponds to any auxiliary lighting the trailer 100 may have. The particular number and/or layout of the connection elements 120A-G should not be deemed limiting.

Disposed on the outer surface 115 of the cylindrical plug body 114 is an alignment projection 116. The lighting receptacle 110 likewise perferably includes a projection recess 117 configured to receive the alignment projection 116. In this way, the cable plug 112 may engage with the receptacle 110 in only one direction. That is, the alignment projection 116 provided on the cable plug 112 and recess 117 on the receptacle 110 ensure that the corresponding pins and sleeves (120A-G) correctly connect. Of course one skilled in the art will recognize that structurally and functionally equivalent alignment arrangements can be used without departing from the scope and intent of the present invention.

Generally, a truck provides a cable, such as cable 111, from the truck to the trailer receptacle 110 such that the controls within the truck cab can power and activate each of the plurality of lighting elements of the trailer 100 described above. The cable 111 is usually a coiled electrical cable with a cable plug 112 adapted to fit into the trailer's lighting receptacle 110. The truck is a powered system including a power supply such as a battery or alternator. The power system provides electrical power to the truck/cab and also allows for the transmission of power to the trailer 100 via cable 111. That is, the controls in the truck cab may activate the lighting elements of the trailer 100 via the connected cable 111.

Logically, given the size of the trailer 100, it would be difficult for a single person to inspect and verify the operation of each of the plurality of lighting elements located on the trailer 100 in a short time. For example, in order for a driver to check the operation of the rear tail lights 108, the rear tail lights 108 must first be activated via controls within in the truck cab. The driver must then leave the cab and walk the length of the trailer 100 to confirm the operation of the rear tail lights 108. This must be done for each of the plurality of lighting elements of the trailer 100 and thus, would require the driver to make multiple lengthy trips around the trailer 100. This may cause delays in departure time of the truck.

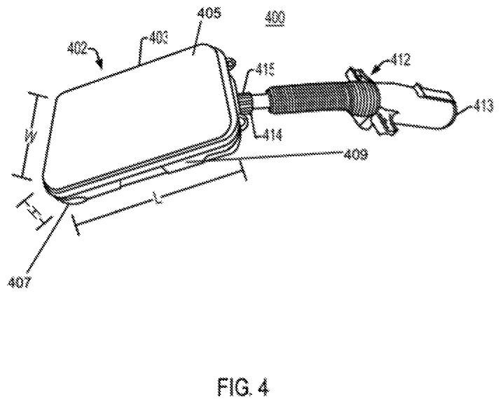

FIG. 2 illustrates a trailer light tester device 400 in accordance with an example embodiment of the subject disclosure. It will be appreciated that the various components depicted in FIG. 4 for purposes of illustrating aspects of the exemplary hardware, software, or a combination thereof, are capable of being substituted therein.

In FIG. 4, various components of a trailer tester device 400 are shown. The trailer tester device 400 includes a main body 402 configured to house associated electrical components and a connector portion 412 configured to connect the electrical components within the main body 402 to a trailer, such as trailer 100 of FIG. 1. The connector portion 412 includes a trailer end 413 and a universal end 414. The trailer end 413 is configured to connect to a corresponding lighting receptacle of a trailer, such as receptacle 110 of a trailer 100. However, it is to be appreciated that receptacles for trailers may vary. In the exemplary embodiment of FIG. 4, the connector portion 412 is shown as a semi-truck trailer connector (cable plug 112) illustrated in FIG. 3.

The main body 402 of the trailer tester device 400 is relatively small. The main body 402 is a housing 403 having a length L, width W, and height H. In some embodiments, the length L is less than about 10 inches. In some embodiments, the length L is preferably from about 5 inches to about 8 inches and more preferably about 6.0, 6.25, 6.5, and 6.75 inches. In some embodiments, the width W is less than about 8 inches. In some embodiments, the width W is preferably from about 3.5 inches to about 5.5 inches and more preferably about 4.0, 4.1, 4.25, 4.5, and 5.0 inches. In some embodiments, the height H is less than about 4 inches. In some embodiments, the height H is preferably from about 1.25 inches to about 3 inches and more preferably about 1.75, 2.0, 2.15, 2.25, and 2.5 inches.

The housing 403 is a rigid structure that retains the circuitry components of the trailer tester device 400. In some embodiments, the housing 403 is rectangular in shape, that is, the housing is box-like. In some embodiments, the housing 403 is made of plastic material, for example and without limitation polycarbonate or urethane, although alternative plastic materials may be used with and without departing from the scope and intent of the present disclosure. In some embodiments, the housing 403 includes a top portion 405 and a bottom portion 407 that when combined define an interior cavity that retains the circuitry components therein. In some embodiments, the housing 403 includes at least one hinge 409 configured to connect the top portion 405 and bottom portion 407 together such that the housing 403 may be opened. When the two-part housing 403 is in an open state, a user may have access to the interior cavity and circuitry components contained therein. In some embodiments, the interior cavity of the housing 403 may provide a storage, for example, for a remote 470 or charging cable 452.

The main body 402, including all components housed within, is lightweight. That is, in some embodiments, the main body 402 weighs less than about 5 lbs. In other embodiments, the main body 402 weighs less than about 2 lbs. In yet other embodiments, the main body 402 weighs preferably from about 1.5 lbs to about 2 lbs. and more preferably about 1.75 lbs and about 1.8 lbs.

The small shape and lightweight properties allow the trailer tester device 400 to be easily portable. Furthermore, when the main body 402 and connector portion 412 are connected, the main body 402 does not stress the connection points between the universal connector end 414 and universal connector 404 of the device. The size and weight properties of the trailer tester device 400 also allow for the device 400 to connect to a trailer receptacle 110 without applying much stress to the connecting elements of the receptacle 110. In this way, the trailer tester device 400 can hang from the trailer receptacle 110 without damaging components of either the trailer tester device 400 or receptacle 110.

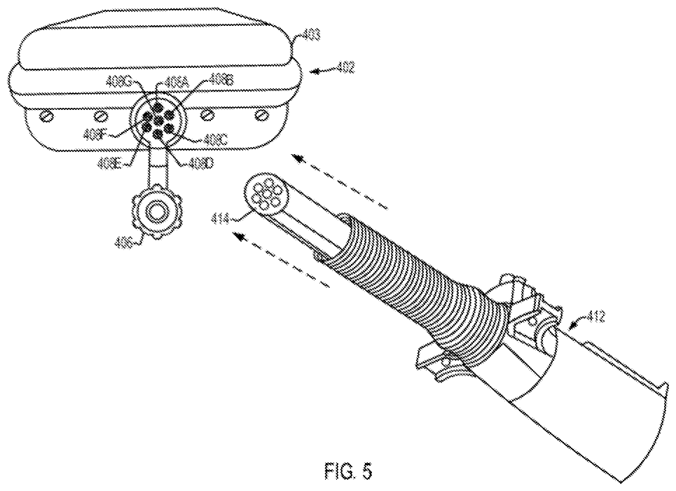

FIG. 5 illustrates a front view of the main body 402 and a universal connector 404. In some embodiments, the main body 402 includes a universal connector cover 406. The universal connector cover 406 is configured to mechanically attach to and protect the universal connecting elements 408A-F from the environment. In some embodiments, the universal connector cover 406 may be a snap fit cover. That is, when pressure is applied to the cover 406 while placed over the universal connector 404, the universal connector cover 406 snaps in a secured state over the universal connector 404. In some embodiments, the universal connector 404 includes a set of external threads and the cover 406 includes corresponding interior threads such that the universal connector cover 406 may be rotated about the external threads of the connector in order to secure and remove the cover 406 from the universal connector 406. In some embodiments, the cover 406 provides a seal to limit ingress of moisture into the connection.

The universal connector 404 of the main body 402 is generally configured to receive the universal connector end 414 of the connector portion 412. The universal connector 404 and connector portion 412 have corresponding pin and sleeve connectors (universal connection elements) such that electrical connection between each are made when the universal connector end 414 is engaged with the universal connector 404.

In some embodiments, the universal connector end 414 mechanically engages the universal connector 404. In these embodiments, the mechanical engagement allows the connector portion 412 to removably attach to and support the main body 402. When the connector portion 412 while engaged with the universal connector 404 is able to bear the weight (load) of the main body 402. That is, when the connector portion 412 and main body 402 are mechanically engaged via the universal connector 404, the main body 402 and connector portion 412 is a rigid unit, i.e., perferably the main body 402 is not loose/allowed to swing/pivot in relation to the connector portion 412.

In some embodiments, the connector portion 412 includes a threaded cap end 415 which engages threads of the universal connector 404. When the threads are engaged, the connector portion 412 is secured to the main body 402

The universal connector 404 also includes a plurality of connection elements, illustrated as elements 408A-G. In some embodiments, the universal connector 404 has seven (7) connection elements 408A-G. Having seven connection elements allows the trailer testier device 400 to test the lights of a semi-truck trailer 100 wherein the lighting receptacle 110 of a semi-truck trailer 100 is a 7 connection element device.

The exemplary universal connector 404 shown in FIG. 4, is illustrated with a total of seven (7) connection elements 408A-G, (pins or sleeves) embedded within a cylindrical plug body. Generally, connection element 408A is a ground, connection element 408B corresponds to the tail lights of a trailer, such as trailer 100 above, connection element 408C corresponds to the right markers of a trailer, connection element 408D corresponds to the stop lights of a trailer, connection element 408E corresponds to the left markers of a trailer, connection element 408F corresponds to the overhead clearance lights of a trailer, and connection element 408G corresponds to any auxiliary lighting associated with the trailer 100.

It is to be appreciated that when the connector portion 412 is a semi-truck trailer similar to connector 112, the connection elements 408A-G correspond to the connection elements of a lighting receptacle 110 of a trailer 100. Said another way, the connector portion 412 is an adaptor between the main body 402 and trailer receptacle 110.

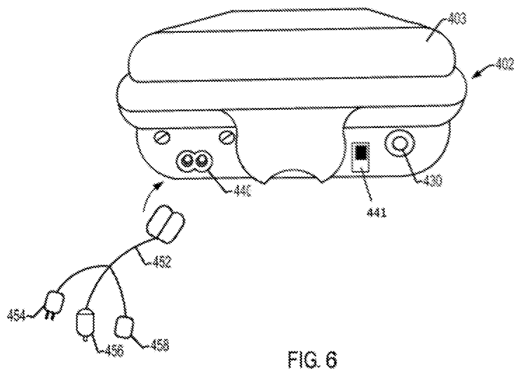

In some embodiments and illustrated in the exemplary embodiment of FIG. 6, the front of the main body 402 includes a lighting element 430. The lighting element 430 may be a lamp or light bulb, LED, or any light emitting device. The lighting element 430 may be configured to emit light when the device is connected to a trailer 100, may emit light when power is selectively applied to the lighting element 130 (e.g., by a switch), or may emit light when the device 400 is in an ON state (activation of a master power switch, described in greater detail below). For example, when a trailer tester device 400 is in an ON state, that is, it is in a powered/activated state, the lighting element 430 emits light indicating that the testing device is ON/in an ON state.

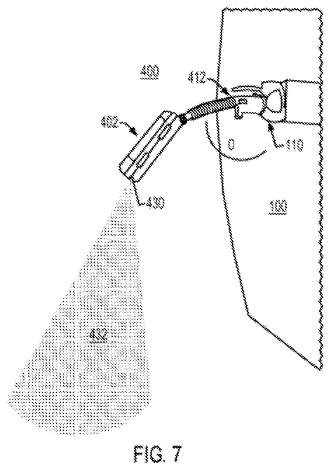

As illustrated in the exemplary embodiment of FIG. 7, the lighting element 430 is configured to emit light 432 in a direction away from the trailer 100. That is, when the trailer tester device 400 is attached to and assembled/sealed as a solid unit, is projecting from a trailer 100, the lighting element 430 produces outwardly facing light 432. The lighting element 430 is incorporated into the main body 402 and housing 403. The emitted light 432 illuminates the immediate area such that an operator of the trailer tester device 400 can visually see the immediate surroundings in otherwise low lighting conditions (nighttime). Furthermore, the lighting element 430, when emitting light, indicates to others that the tester device is in operation and that an operator is performing testing on that trailer.

The incorporated lighting element 430 is particularly useful in truck yards where there are many trailers parked and trucks are continuously driving and backing into trailers for connection. The lighting element 430 is present at a height (when plugged into the trailer receptacle 110) such that the emitted light 430 is in the view of a driver of another truck. The lighting element 430 signals to the driver that the associated trailer is being tested, e.g., pre-trip inspection. Thus, the driver should (1) not back into the trailer 100 for connection; and/or, (2) be aware of an operator on the ground testing the trailer lights.

In some embodiments, the lighting element 430 is an LED. The LED may emit light in any color. In some particular embodiments, the lighting element produces light that is blue in color.

With reference back to FIG. 6, the main unit 402 includes a master On/Off switch 441. Although illustrated as being located on a surface opposite to that of the device surface including the universal connector 404, it is to be understood that the switch 441 may be located anywhere on the housing 403 such that it is accessible by a user of the trailer tester device 400. The On/Off switch 441 may be variously embodied as a slide switch, toggle, button, rotary dial, or any device known in the art that enables and disables power distribution from the power supply. When the switch 441 is positioned in an OFF position, the device is in an OFF state such that a circuit of the components to a power source is broken and the components within the circuit (processor, wireless communication device, etc.) are unpowered. In the OFF state, the drain on an associated power supply, such as a battery, is minimal and the trailer tester device 400 may be stored in-between uses while retaining the majority of its power supply without the need to recharge. When the switch 441 in positioned in an ON position, the trailer tester device is in an ON state (powered state) such that the circuit components are powered by the power supply and the trailer tester device is operable. In some embodiments, when the trailer tester device 400 is in the ON state, the lighting element 430 is powered and emits light to indicate the powered status of the device 400.

With continued reference to FIG. 7, the trailer tester device 400 is configured such that it may be completely supported by the lighting receptacle 110 of a trailer 100 when the connector portion 412 is inserted therein. That is, rather than hanging down due to the force of gravity from the lighting receptacle 110, the trailer tester device 400 projects outwardly from the trailer 100. In some embodiments, the trailer tester device 400 projects outwardly and at an angle θ of less than 90 degrees, wherein the angle 9 is defined as the angle between the surface of the trailer 100 and trailer tester device 400. In some embodiments, angle θ is less than about 80 degrees. In some embodiments, the angle θ is from about 30 degrees to about 60 degrees. The angled attachment allows for truck drivers to visually see the lighting element 430 and for the lighting element to illuminate the immediate area.

In some embodiments and with reference back to FIG. 6, the trailer tester device 400 includes a power port 440. The power port 440 is a sealed port that connects an electrical cable to the internal circuit of the device 400. The power port 440 may be a 2-slot receptacle, USB-port, USB-C port, micro USB port, mini-USB port or any receptacle configured to receive and connect to a likewise configured power cord 452. In some embodiments, a power cord 452 is configured to deliver electrical power to the trailer tester device 400 as a power supply in order for the testing device 400 to operate. Although illustrated as being located on a surface opposite to that of the surface including the universal connector 404, it is to be understood that the power port 440 may be located anywhere on the housing 403 such that it is accessible by a user of the device. In other embodiments and described in greater detail below, the power cord 452 is configured to deliver power to an associated rechargeable power source of the trailer tester device 400 in order to recharge the power source.

In some embodiments, the trailer tester device 400 includes a power supply 450. The power supply 450 may be a battery. In some embodiments, the power supply 450 includes a plurality of battery cells sufficient to generate about 12.0 volts or an equivalent voltage to power automotive lighting, for example and without limitation the plurality of lighting elements of an associated trailer. In some embodiments, the power supply 450 may generate from about 10 volts to about 14.5 volts. In some embodiments, the power supply is internal to the housing 403.

In some embodiments, the power supply 450 is an internal rechargeable battery. The power port 440 described above, may then connect a power cable/charging cable 452 to a charging circuit 456, as known in the art, of the rechargeable battery 450. When power is supplied to the charging circuit 456, electrical charge is delivered to the rechargeable power supply in order to recharge the power supply 450. The charging circuit allows for the recharge of the power supply 450 at a rate wherein no damage is applied to a battery cell. In some embodiments, the charging circuit provides for a slow/trickle charge to the power supply, e.g., provides a full recharge in a time greater than one hour. In other embodiments, the charging circuit provides for a fast charge to the power supply 450, e.g., provides a full recharge in less than an hour. The charging cable 452 may have a traditional outlet plug 454, an automotive accessory plug 456, or a USB type plug 458.

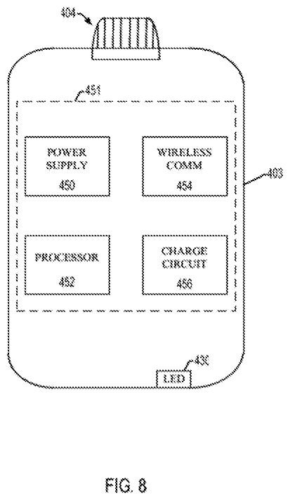

FIG. 8 illustrates an exemplary block diagram of some of the internal components (circuitry) contained within a cavity of the main body 402. That is, the main body 402 is a hollow housing 403 that is configured to house a power supply 450, a processor 452, a wireless communication device 454, and a charging circuit 456 all electrically connected within circuit 451.

The power supply 450 is configured to supply electrical power to the trailer tester device 400 and all electrical components thereof. The power supply 450 may power each component of the circuit 451 including but not limited to the LED 430, the wireless communication device 454, and processor 452. The power supply 450 also provides power to the universal connector 404. That is, the power supply 450 provides electrical power to activate the lighting elements, such as marker lights 102, and 104, clearance lights 106, tail lights 108 and stop lights 109 of a trailer 100.

The power supply 450 may be a collection of battery cells, wherein a cell is a single electrochemical unit that contains electrodes, a separator, and an electrolyte. The battery supplies an electrical current to the trailer testing device 400 and lighting elements of a trailer, such as trailer 100, in electrical connection with the trailer tester device 400. In some embodiments, the power supply 450 is configured to supply power to a 12-volt automotive system, such as the lighting system of a trailer.

In some embodiments, the power supply 450 is or includes a rechargeable battery. That is, the rechargeable battery may be charged by another power supply (e.g., via charging cable 452), discharged into a load, and recharged many times, as opposed to a disposable battery, which is supplied fully charged and discarded after use. In some embodiments, the power supply 450 is a battery with a lithium chemistry, either a lithium ion or lithium polymer battery. These lithium batteries are characterized in that they are light in weight and offer a high energy density (energy/weight or energy/size) while the loss of charge when not in use is minimal.

In some embodiments, the power supply 450 is a battery with a capacity of less than 3000 mAh (milliampere hours). In some embodiments, the battery has a capacity of less than 2500 mAh. In other embodiments, the battery capacity is from about 500 mAh to about 2000 mAh, and more preferably 1000, 1100, 1200, 1300, 1400, 1500, 1600, 1700, 1800 or 1900 mAh.

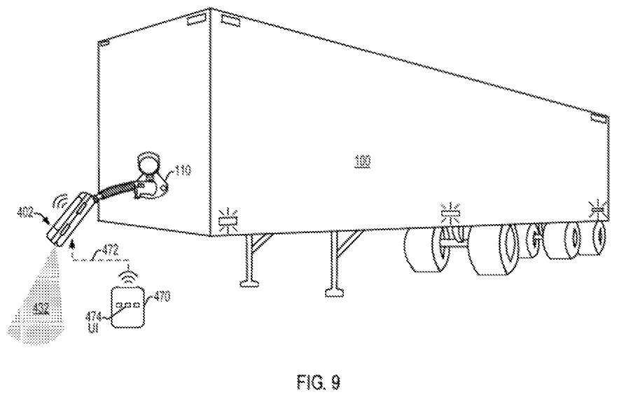

With reference to FIGS. 8 and 9, the trailer tester device 400 may also include a wireless communication device 454 in electrical communion with the power supply 450. The wireless communication device 454 may be a wireless interface such as a Wi-Fi, Bluetooth™, Zigbee™, and radio frequency (RF) interface configured to operatively connect wirelessly to a user remote 470 for activation and control of the trailer tester device 400 and connected trailer lighting elements.

The user remote 470 is capable of producing one or more remote signals 472 that is received by the wireless communication device 454 to enable one or more user commands. Actuation of remote 470 via an associated user interface 474 allows the user to operate various functions of the trailer tester device 400 while eliminating the need to manipulate the trailer tester device 400 itself.

The user remote 470 can connect to the wireless communication device 454 of the trailer testing device 400 through wireless means known in the art including but not limited to Bluetooth, radio frequency (RF), etc. The user remote 470 includes a user input device 474 which may be variously embodied as keys, buttons, switches, and the like for receiving user commands. Although voice actiation is also a possibility, the particular environment and associated ambient noise would suggest that voice activated operation is less desirable. Additionally or alternatively, the user input device 474 may be a touch-sensitive display providing for user input, and/or other user input devices may be provided such as a mouse, trackball, soft keys or so forth.

In some embodiments, the user remote 470 is a smart device, such as a smartphone or tablet that is configured to wirelessly connect to the wireless communication device 454. That is, the smart device, as a user remote 470, is programmed to run a software application providing a graphical user interface having a predetermined set of labeled buttons/switches and the like corresponding to one or more user commands. A processor 452 of the trailer tester device 400 is configured to receive and execute commands from wireless communication device 454 to affect a function of the trailer light testing device 400. In this way, the user will be able to see the function being activated and any status or other visuals regarding the status of the testing device 400, such as what set of lights is currently being activated.

In some embodiments, the wireless communication device 454 is a prefabricated module which contains an onboard microcontroller/processor 424. The onboard processor 424 is configured to execute instructions to direct power from the power supply 454 to each connection element 408A-G of the universal connector 404. In this way, the onboard processor 424 may then cause individual lighting circuits of a connected trailer 100 to activate in a desired protocol.

In some embodiments, the circuitry of the trailer tester device 400 includes a plurality of relays. Generally, a relay is an electrically operated switch. It consists of a set of input terminals for single or multiple control signals, and a set of operating contact terminals. The switch may have any number of contacts in multiple contact forms, such as make contacts, break contacts, or combinations thereof. Relays are used to control a circuit by an independent low-power signal, or where several circuits must be controlled by one signal. Some forms of relays utilize an electromagnet to close or open the contacts. Other forms include solid state relays which use semiconductor properties for control without relying on moving parts. The relay may be used to control the circuit 451 by directing the electrical power signals to a designated target, e.g., electrical pins/connectors that transmit power to an associated receptacle and lighting elements. The trailer tester device 400 may include a plurality of relays, for example, six (6) relays corresponding to each of six (6) separate pins/connectors of the 7-pin universal connector 404. That is, each connector 408B-G is associated with a relay. It is noted that the ground connector 408A is not associated with its own relay. It is to be understood that the number of relays and connectors are non-limiting, and that generally, each output connection port is generally associated with a relay switch.

A processor 452 of the trailer tester device 400 receives a user command (i.e., via a user interface or remote) associated with activating a set of lights on the trailer 100. For example, left marker lights 102 may be considered a set of lights. This may be a command input into the user interface 474 of remote 470. In such a case, the command 475 is wirelessly transmitted to the main unit 402 where it is received by the wireless communication device 454. The processor 452 executes the command and activates a relay associated with the desired command. That is, if the user has requested the left side marker lighting elements 102 to activate, the processor 452 will actuate the relay connected to pin 408E of the universal connector 404. The power from the power supply 450 is directed through the universal connector 404 and connector portion 412 to the lighting system of the trailer 100 accessed via the lighting receptacle 110. The left side mark lights 102, powered ultimately by the power supply 450 of the trailer tester device 400, are activated until the operator can confirm the operation of each marker light 102 (if there are multiple) and a user command is entered to deactivate the particular lighting circuit of the trailer 100.

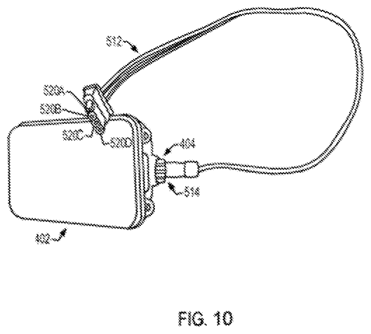

FIG. 10 illustrates the universality of the universal connector 404. That is, the semi-truck adaptor/plug 412 may be disconnected from the main body 402 and another connector portion such as plug 512 may be connected to the main unit 402. The connector plug 512 is illustrated as a UHAUL® plug having four (4) connection elements 520A-D. Here, connection element 520A is ground, connection element 520B is associated with the tail lights of a trailer, connection element 520C is associated the left markers and stop lights and connection element 5200 is associated with the right markers and stop lights.

The connector portion 512 includes a universal plug end 514 which interfaces with the universal connector 404 of the tester device. The plug end 514 and universal connector 404 engage such that pins with like associations are connected. For example, pin 408B of the universal connector 404 makes electrical connection to element 5208 of the connector plug 512. In this way, the user interface 474 of the remote 470 commands the same function no matter what connector plug is used with the device 400.

Likewise, any connector plug having 7 or less connection elements may be interfaced with the universal connector 404 of the device 400. Thus, a single tester device 400 may be used to test the lighting operation of a variety of different trailers. Since trailers often are equipped with a unique lighting receptacle, (semi-trucks utilize a 7-pin connector, boat and vehicle trailers for conventional vehicle towing may have 6, 5, 4 or 3 pin connectors) only different connection portions are needed versus needing separate testing units for each application. The trailer tester device 400 is then capable of using interchangeable connector plugs that may be chosen by a user based upon the trailer for which light testing is desired. In other words, only a single main unit is needed to inspect the operation of trailer lights where the main unit is configured to accept connector plugs having a universal plug portion and a specific trailer plug portion.

In some embodiments, the housing 403 includes an attachment device for removably attaching the unit to a desired location. In some embodiments, the attachment device is a magnet disposed on the bottom surface of the housing 403. In this way, the main unit 402 may magnetically attach to a trailer frame, such as a boat trailer, while an operator operates the tester device 400.

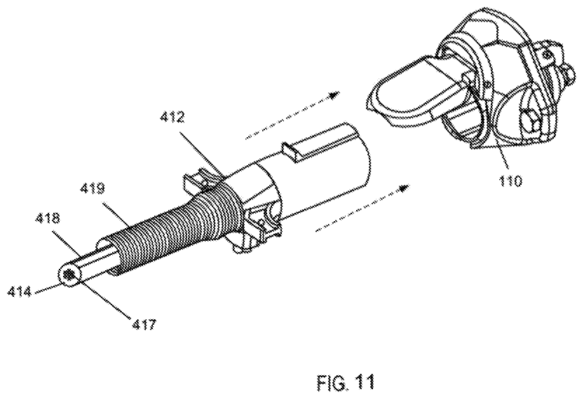

FIG. 11 illustrates a connector portion 412 and a trailer receptacle 110. The connector portion 412 may be inserted and engaged with the receptacle 110 via insertion along the direction indicated by the arrows. The connector portion 412 includes universal end 414 including a plurality of connection elements 417. In some embodiments, the universal end is positioned at the end of a connector wire 418. The connection elements 417 are configured to connect to the connection elements of the universal connector 404.

In some embodiments, the connector portion 412 includes a coiled spring portion 419. The coiled spring portion 419 supports the connector wire 418 such that when the main unit 402 is connected to the connector portion 412 via universal connection 404, the main unit 402 projects outwardly when the device is installed in a trailer receptacle 110.

The exemplary embodiments have been described with reference to the preferred embodiments. Obviously, modifications and alterations will occur to others upon reading and understanding the preceding detailed description. It is intended that the exemplary embodiments be construed as including all such modifications and alterations insofar as they come within the scope of the appended claims or the equivalents thereof.

To aid the Patent Office and any readers of this application and any resulting patent in interpreting the claims appended hereto, applicant does not intend any of the appended claims or claim elements to invoke 35 U.S.C. 112(f) unless the words “means for” or “step for” are explicitly used in the particular claim.

1. A tester device for testing the functions of a trailer comprising:
a main unit comprising a housing holding a power supply; and,
a connection interface comprising a plurality of first connection elements, the connection interface configured to removably connect the main unit to a connector portion comprising a plurality of second connection elements, wherein the connector portion includes:
a first end configured to mechanically engage the connection interface wherein one of each of the first connection elements is electrically connected to one of each of the second connection elements; and,
a second end configured to engage a trailer receptacle, wherein the connector portion electrically connects each of the first connection elements of the connection interface to the trailer receptacle.

2. The tester device according to claim 1 further comprising a wireless communication interface located within the housing and in communication with the power supply; wherein the wireless communication interface is configured to wirelessly communicate with a remote comprising a user interface

3. The tester device according to claim 1, wherein the connection interface is a 7-pin connector having 7 connection elements.

4. The tester device according to claim 2, wherein the remote is a smart device such as a smartphone, or tablet.

5. The tester device according to claim 1, wherein the power supply is a battery.

6. The tester device according to claim 5, wherein the battery is a rechargeable battery.

7. The tester device according to claim 5, wherein the battery comprises lithium ion or lithium polymer based chemistry.

8. The tester device according to claim 5, wherein the battery has a capacity less than 3000 mAh.

9. The tester device according to claim 1, wherein the main unit weighs from about 1.5 lbs. to about 2 lbs.

10. The tester device according to claim 1, wherein the housing has a, length from about 5 inches to about 8 inches, a width from about 3.5 inches to about 5.5 inches and a height from about 1.25 inches to about 3 inches.

11. The tester device according to claim 1, wherein the tester device is configured to mechanically engage with the trailer and project outwardly from a surface of the trailer.

12. The tester device according to claim 11, wherein the tester device projects outwardly at an angle, the angle defined between the surface of the trailer and device, wherein the angle is from about 30 degrees to about 60 degrees.

13. The tester device according to claim 1 further comprising a lighting element.

14. The tester device according to claim 1, wherein the connection interface is configured to removably engage interchangeable connector portions.

15. The tester device according to claim 1, wherein the connection interface and connector portion comprises a corresponding threaded attachment cap for securing the connector potion to the connector interface.

16. A tester device for testing the functions of a trailer comprising:
a power supply;
a connection interface including a plurality of connection elements;
a plurality of relays in electronic communication with the power supply and the connection interface, wherein each relay of the plurality of relays is associated with one connection element of the plurality of connection elements;
a processor in electronic communication with the plurality of relays configured to actuate at least one relay, wherein actuation of the at least one relay allows the transfer of electric power from the power supply to the associated connection element;
wherein the associated connection element is configured to supply power to a trailer connection element in order to operate a function of the trailer.

17. The tester device according to claim 16 further comprising a wireless communication interface in electronic communication with the processor; wherein the wireless communication interface is configured to wirelessly communicate commands to the processor for actuating at least one relay of the plurality of relays from an associated remote comprising a user interface.

18. The tester device according to claim 16, wherein the connection interface is configured to removably connect to a connector portion, wherein the connector portion includes a first end configured to mechanically engage the connection interface and a second end configured to engage a trailer receptacle.
